(19) United States
(12) Patent Application Publication
(10) Pub. No.: US 2022/0091159 A1
(43) Pub. Date: Mar. 24, 2022

(54) High Current Component

(71) Applicant: Roman Nachsel, Seddiner See OT Neuseddin (DE)

(72) Inventor: Roman Nachsel, Seddiner See OT Neuseddin (DE)

(21) Appl. No.: 17/425,305

(22) PCT Filed: Jan. 21, 2020
(86) PCT No.: PCT/EP2020/051428

§ 371 Date: Jul. 22, 2021

(30) Foreign Application Priority Data
Jan. 22, 2019 (DE) 10 2019 101 510.3
Aug. 15, 2019 (DE) 10 2019 121 980.9

(51) Int. Cl. G01R 15/14; H05K 1/02

(52) U.S. Cl. CPC G01R 15/148; H05K 2201/10106; H05K 1/0274; H05K 1/0263

(57) ABSTRACT

A functional electronics unit for a high current component which is provided for electrical and mechanical connection to a circuit board or to another mechanical carrier substrate for a circuit grouping or circuit, with conductor tracks, conductive surface elements and/or other conductive regions and contacts, the functional electronics unit having electronic components which are designed to measure properties of the electric current flowing through the component or of an electric voltage applied to the component or to perform another electronic functionality, is characterized in that the functional electronics unit is retained on the high current component or on a common carrier. More particularly, the functional electronics unit can be integrated into the high current components and/or can be pushed onto the high current component in a modular fashion or can be fixed on the high current component.

### TECHNICAL FIELD

The invention relates to a functional electronics for a high current component which is provided for electrically and mechanically connecting to a printed circuit board or another mechanic carrier substrate for a circuitry or a circuit having conductive paths, conductive area elements and/or other conductive ranges and contacts which are designed for high currents wherein the functional electronics is provided with electronic parts which are suitable for measuring the properties of the electric current flowing through the component or an electric voltage applied to the component or for carrying out another electronic functionality.

Furthermore, the invention relates to a high current component for electrically and mechanically connecting to a printed circuit board or another mechanic carrier substrate for a circuitry or a circuit having conductive paths, conductive area elements and/or other conductive ranges and contacts which are designed for high currents.

A high current component is, for example, a press-fit component or a plug-in element. A high current component is mechanically and electrically connected to a printed circuit board or another carrier substrate. Such component may, for example, assume the shape of large screws which are anchored in a slot on the printed circuit board. The component will then form a contact within the circuit having high currents flowing therethrough.

In particular, circuits and the corresponding functionalities are realized on such printed circuit boards. There are further mechanical alternatives to realize circuits, such as discretely using individual components. Circuits with low currents, such as integrated circuits in the computer industry are distinguished from high current circuits. High data rates with high bandwidth can be transmitted by small currents, for example in SMD technology.

High current components can be used with different mechanical carrier substrates associated with a circuit assembly or a group of circuits. For simplicity it is referred to below as printed circuit boards. It is understood, that the invention can be accomplished with different mechanical carrier substrates.

High current circuits are used, for example, for railway technology. The currents in high current circuits can be several tens up to some hundreds Ampere. Accordingly high current circuits have relatively thick cables with large cable cross section. Large insulation distances must be adhered to due to the occurrence of potentially high voltages. Since the power required for soldering such cables cause high temperatures and mechanical stress the contacts are established on the printed circuit board by means of press-fit component or plug-in elements.

### PRIOR ART

High current components for contacting on printed circuit boards are, for example, sold by Würth Elektronik eiSos GmbH & Co.KG under the name of “Press-fit”, Würth Elektronik ICS GmbH & Co. KG, BROXING SA under the name of “Power Clamp”, TE Connectivity and ERNI Electronics GmbH & Co. KG.

For the production of a printed circuit board, at first a function circuit diagram is defined for a circuit to accomplish the functionality desired to be accomplished with the printed circuit board and the circuit present thereon. A circuit diagram is then established and the installation space analysis carried out. Only thereafter the layout is carried out, i.e. the design of the functional components.

It is often necessary for complex circuits to measure the physical conditions at a contact and display them. For example, it may be necessary to measure and display the current flowing through a press-fit component or the voltage at the press-fit component, in order to assess if the corresponding values are within a selected value range. Other physical conditions may also be relevant, such as the temperature. For detecting such physical conditions, measuring assemblies or other functional electronics are used in addition to the high current circuit itself. The functional electronics provides information about the conditions within the circuit and in particular, if the high current circuit operates as it should.

The additional sensor system or other functional electronics is a low current application. Accordingly, hybrid manufacturing technologies must be used for such a printed circuit board. The additional functional electronics must undertake the same proceedings for certification as all other parts on the printed circuit board and the printed circuit board itself. The functional electronics must also be considered when planning the installation space. This means, that a certain soldering effort is necessary during manufacturing. Each solder joint has a failure probability. The more parts that are used, the higher is the risk of failure. Thereby, known assemblies and their functional design is complex. Each time a part is changed in a high current circuit, the entire assembly, i.e. the unchanged parts, too, must undergo a new certification proceedings. This is expensive and costs a lot of time and it requires much competence of the responsible staff.

### DISCLOSURE OF THE INVENTION

It is an object of the invention to simplify the development and manufacturing of high current printed circuit boards. According to the present invention this object is achieved in that the functional electronics is held at the high current component or a common carrier. In particular, it may be provided that the functional electronics can be mounted together with the high current component.

It may also be provided that the functional electronics is adapted to be integrated into the high current component. The term “integrated” is understood in such a way that the functional electronics is either provided in a cutout or in a cavity or on the outside of the high current component or fixed to a common carrier. The common carrier can be formed by a carrier material, such as, for example, resin into which the functional electronics is molded in. A plate or the like may also be used, the functional electronics being mechanically fixed thereon. The design of the functional electronics is adapted to the respective application and can, but must not necessarily comprise itself a printed circuit board or a carrier substrate.

Alternatively or additionally a housing or a carrier material may be provided adapted to have the functional electronics modularly stuck thereon or the functional electronics being fixed to the high current component. The insulation distance to further parts can also be secured by such housing.

Furthermore, it can be provided that the functional electronics is adapted to be inserted into a cutout or into a cavity within the high current component.

The functional electronics does not need to be individually planned and considered for each printed circuit board. Instead, it is standardized and held at the high current component. It can be certified within the component or in relation thereto and simplifies the planning, examination and certification of the printed circuit board. The installation space may also be easily planned and the soldering efforts are reduced or avoided altogether. Examples of a functional electronics are, in particular, the measuring of the current flowing through the component, the measuring of a voltage applied to the component, the measuring of the temperature in or at the component or a value representing the temperature. Also, further sensors may be integrated in the component. Other functionalities may also be accomplished with the functional electronics. This includes in particular, the assessment whether a contact is established or not.

The measuring of the current can be effected, for example, by measuring and evaluating the magnetic field surrounding the conductor. The actual current signal is practically not affected thereby. It is, however, also possible to use other technologies or measuring methods for the sensors. The contacts can be all provided at one side of the component, such as, for example, on the side facing the printed circuit board. Some of the contacts can be provided for digital signals while other contacts are provided for the other signals, such as possibly required reference potentials.

Typically, the high current component has contacts for contacting the printed circuit board having the high current flowing through. In addition to such contacts for contacting with the printed circuit board, preferably contacts are provided which are galvanically de-coupled from the other contacts of the high current component and where signals of the functional electronics are present and can be tapped or applied. Information can be exchanged with devices for further processing at such additional contacts.

In a further modification of the invention it is provided that the functional electronics comprises an optical and/or acoustic signal generator, which indicates the presence or absence of a state of the component. Such an optical signal generator can comprise, in particular, one or several LED or OLED. It is, however, also possible to use different optical signal generators. In an alternative embodiment of the invention it is provided that the signal generator is not provided within the functional electronics, but at a different place.

In a further modification of the invention it is provided that the functional electronics is provided with at least one data interface adapted to configure one or more electronic parts comprised in the functional electronics. The functionality of the component may then be individually adapted to the respective application by simple programming and/or configuration. The configurability enables the manufacturing of the high current component with high numbers even if only small numbers are required for the individual configuration.

In a further modification of the invention the functional electronics is provided with an IO-link or any other standardized communication interface. Data generated by the functional electronics, in particular measuring values and set-up values can be transmitted through the communication interface to further devices and functional groups and used or further processed there.

Alternatively or additionally to such a communication interface an optical communication interface may be provided. Preferably, but not necessarily, the communication interface is bidirectional. In particular an optical fiber can be provided which is configured to receive the optical signals of a signal generator for transmitting the signals to a processing unit. It is understood that different means for transmitting the optical signals may also be suitable. Optical fibers are fibers, tubes or sticks which can transport light along short or long distances. Optical fibers are, for example, individual glass fibers or bundles with several glass fibers. Different light wave conductors (LWL), glass fiber cables or light conducting cables (LLK) may also be used.

It is a considerable problem causing a risk of failure if signals are electrically transferred through cables to and from the functional electronics. The cables must then be galvanically separated and/or decoupled which generally comprises measures for electromagnetic compatibility. This is associated with high efforts and expenses during manufacturing and quality control. Contrary to electric signals which are transferred via electric lines on the circuit board to the outside, a galvanic separation implicitly occurs when communicating optically and therefore, no further measures for the separation are necessary on this line path. Optical signals are not affected even by high currents and voltages and their changes and have, therefore, a smaller risk of failure for physical reasons. The optical transmission enables high bandwidths and can be put into practice at low costs. The line length of the signal path for the analog measuring signal and its detection and possibly the pre-processing is advantageously kept short. The signal is converted and digitally transmitted towards the outside on an optical path. The controlling may be effected in the same way.

The voltage supply of the functional electronics is preferably a suitable voltage which is present in the form of a potential difference on the printed circuit board. Such means may also be used to generate an optical signal. When designing possible voltage sources of the functional electronics respective industry standards and norms must be adhered to. If no reference potential is present on the printed circuit board such a further reference potential must be provided. This can be the case, for example, if the high current component including the functional electronics is provided on a single potential trace of thick copper (>several hundreds of microns).

The optical fiber can be guided, for example, perpendicularly upwards, through the printed circuit board perpendicularly downwards, parallel above the printed circuit board or through a slit parallel below the printed circuit board. The permitted curvature radii of the fiber must be considered. A communication can be uni- or bidirectional. For this purpose one or more optical fibers can be used. In particular, a bidirectional communication enables the configuration of the functional electronics in one direction and the signal transmission of the measuring values and status information in the other direction.

Relating to the directionality of the communication paths depending on the design of the functional electronics all operating modes can be used (simplex, half-duplex, full-duplex and dual-simplex).

The object is also achieved with a high current component which has a functional electronics which is held at the high current component or a common carrier.

In particular, the high current component may be designed as a press-fit component, as a screw element, for snap-in contacts, touch fastener (Klettverbindung) fastenings or designed as a plug-in element. Other connecting, contacting, and fixing options are also possible. A touch fastener is, for example, described in DE 10 2017 126 724 A1.

Preferably, the component consists of the functional electronics and otherwise only of a coated or uncoated, homogenous, electrically conductive material.

In an exemplary modification of the invention it is provided that the component comprises an electrically conducting metal body and the functional electronics is provided in a cutout or in a cavity within such metal body. This is advantageous since the outer diameters of the high current component almost remain the same as known components without a functional electronics. In an alternative embodiment of the invention it is provided that the functional electronics is plugged on the high current component or fixed on its outside. The functional electronics may form a module for upgrading known high current components.

Typically the high current component has contacts for contacting the printed circuit board where the high current flows through. In addition to these contacts for contacting the printed circuit board, preferably contacts are provided which are galvanically de-coupled from the rest of the contacts and where signals of the functional electronics can be obtained or fed from the outside. Information can be transferred to devices for further processing and, for example, control signals can be received at such additional contacts.

In particular, the high current components are designed for currents above 16 A, preferably above 50 A and most preferably above 100 A. These are current and power ranges which are several orders of magnitude larger than the ranges which are used in typical electronics in IT and telecommunication.

Furthermore the high current component can be characterized in that a thread, a plug-in contact or another surface contact is provided for connecting high current lines.

The target of the manufacturing and the subsequent use of a printed circuit board is a vibration resistant, simple assembling, which is exposed to as little thermal and mechanical stress as possible. If soldering can be avoided, error sources and manufacturing caused thermal stress will mostly not occur. During press-fit operation of contacts, typically a large pressure is exerted. Connections in the form of snap-in contacts (for example Skedd, www.skedd.de) or touch fastener (Klettverbindung) connections as described in DE 10 2017 126 724 A1 can be used for the cables, in particular for control signals and reference potentials, which require less pressure for inserting.

The electric conductors for elements receiving high currents may be made of pure materials, such as copper or alloys such as brass. It is important that they are pressure resistant, have a high conductivity and do not oxidize easily. Oxides can form unwanted insulating spots. In order to reduce such an effect, the conductors can be, for example, surface treated, such as galvanized, tin coated or gold plated. It does not do any harm if the coating material is soft because this will cause good form fitting when press-fitting.

An at least partial insulation of the housing or the carrier for the functional electronics on the side facing the printed circuit board or the carrier substrate generally makes sense in order to achieve an additional insulation and de-coupling for interferences with respect to possibly present conductor lines, such insulation being better than the mere solder resist of the printed circuit board. Without such finish or if another mechanical carrier substrate is used instead of a customary printed circuit board a different insulation may be used also.

There are press-fit elements having a through bore for receiving the cable. A counter part can be inserted from below into the through bore.

In a further modification of the invention a high current component is provided which is characterized in that
(a) the functional electronics is arranged in or upon a carrier material or in a housing which cannot be removed from the carrier substrate without destruction, wherein
(b) the carrier material of the functional electronics is galvanically separate from the carrier substrate of the parts; and
(c) the carrier material or housing is provided with further cutouts for further threads, plug-ins or other surface contacts for connecting high current lines which together use at least portions of the functionality of the functional electronics.

Such an alternative enables, for example, the measuring of phase related properties of current and voltage or other physical measuring values in a multi-phase alternating current circuit. A voltage source for the functional electronics can be provided, for example, by occurring potential differences between the individual phases. Such an alternative enables the use of advantages of the presence of several high current potentials or signals which must be considered in relation to each other and the possible expandability of existing circuits.

Further modifications of the invention are subject matter of the subclaims. An embodiment is described below in greater detail with reference to the accompanying drawings.

### DEFINITIONS

In this description and in the accompanying claims all terms have the meaning well known to the person skilled in the art which is defined in technical literature, norms and the relevant internet sites and publications, in particular of the lexical kind, such as www.wikipedia.de, www.wissen.de or www.techniklexikon.net, www.skedd.de, of competitors, research institutes, universities and associations, such as, for example, Verein Deutscher Ingenieure. In particular, the terms used here have not the opposite meaning of what the person skilled in the art will derive from the above publications.

### BRIEF DESCRIPTION OF THE DRAWINGS

FIG. 1 shows a high current component with an integrated functional electronics according to a first embodiment.

FIG. 2 is a perspective representation of a contact adapter for the high current component of FIG. 1.

FIG. 3 is a perspective representation of the high current component of FIG. 1 with a press-fit component without contact adapter.

FIG. 4a illustrates the available installation space for the functional electronics within the high current component of FIG. 1.

FIG. 4b schematically shows a functional electronics which can be, by way of example, arranged in the available installation space shown in FIG. 4a. It is understood that different functional electronics may also be installed.

FIG. 5 is a top view on a high current component of FIG. 1.

FIG. 6 is a side view of the high current component of FIG. 1.

FIG. 7a is a perspective representation of a high current component according to a second embodiment with an integrated functional electronics where the top-side can be seen.

FIG. 7b schematically shows a functional electronics which can be positioned in the exemplary available installation space in the high current component of FIG. 7a provided for this purpose. It is understood, that different functional electronics may also be installed.

FIG. 8 is a perspective view of a high current component with an integrated functional electronics according to a second embodiment where the underside with contacts is visible.

FIG. 9 is a top view of the high current component of FIG. 7.

FIG. 10 is a side view of the high current component of FIG. 7.

FIG. 11 is a perspective representation of a printed circuit board with a high current component having an external signal generator on its underside.

FIG. 12 is a cross section through the printed circuit board with a high current component on the top side with an integrated signal generator and a perpendicularly extending optical fiber.

FIG. 13 is a perspective representation of a printed circuit board with a high voltage component where the optical fiber extends through the printed circuit board and parallel with respect to the printed circuit board.

FIG. 14 is a cross sectional view of the assembly of FIG. 13.

FIG. 15 is a semi-transparent side view of a functional electronics with three placed high current components.

FIG. 16 is a perspective view of a high current component for the assembly of FIG. 15.

FIG. 17 is a perspective outer view of the assembly of FIG. 15.

FIG. 18 is a perspective, semi-transparent view of the functional electronics of FIG. 15.

FIG. 19 schematically shows a functional electronics for the assembly of FIG. 15, which can be mounted in the available installation space by way of example. It is understood that other functional electronics may also be installed.

### DESCRIPTION OF THE EMBODIMENT

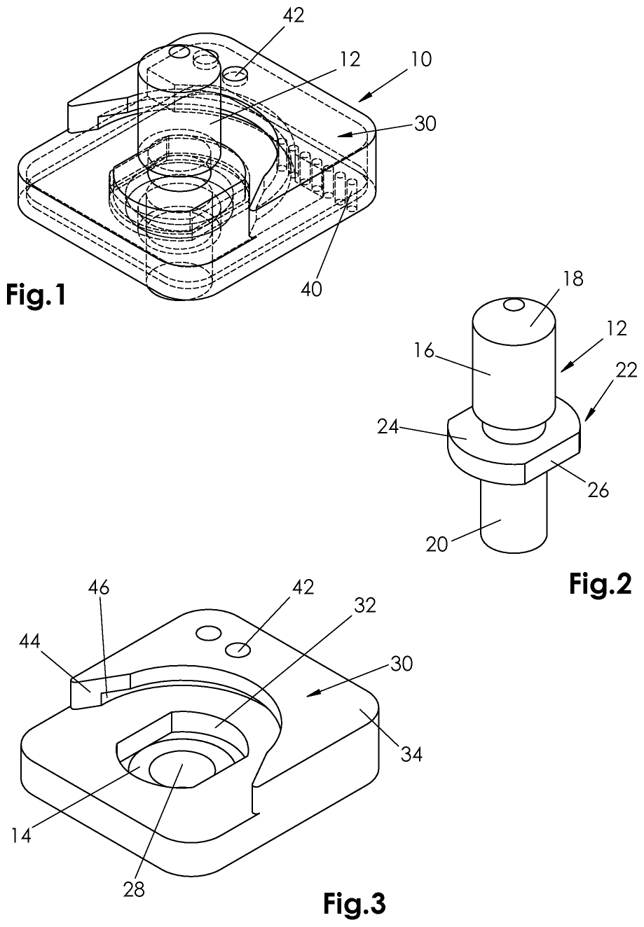

FIG. 1 to FIG. 6 show a first embodiment of a high current component generally designated with numeral 10. The high current component 10 is built-on modular. A first module is formed by a commercially available contact adapter 12. This is shown in FIG. 2. The contact adapter 12 sits in a press-fit component 14. The press-fit component is annular and can be recognized in FIG. 3. Such contact adapters 12 and press-fit components 14 are disclosed, for example, on the sites https://powerelement.we-online.de/products and https://hdm-innowema.de/f/tk_tacksert_pins.pdf. It is understood that the shown contact adapter 12 and the press-fit component 14 may vary with respect to its form and material and are shown here by way of example only. Alternatively the press-fit component can be individually inserted.

The contact adapter 12 is provided with a cylindrical contact 16 at its upper end in FIG. 2. The upside 18 of the contact is conically shaped. A conductor or the like can be connected to the contact 16 as it is well known from the art to the person skilled in the art. In particular, a high current cable can be connected thereto. The contact 16 forms part of a cylindrical body 20. The electrical connection between the press-fit component 14 and the conductive parts of the printed circuit board, also called PCB (not shown) is established through the cylindrical body. A rotation lock 22 forms part of the cylindrical body 20 in the middle range of the contact adapter 12. The rotation lock 22 of the present case has the form of a circular plate 24 extending parallel to the plane of the printed circuit board and being cut off at two opposite ends 26. The cylindrical body 20 extends through the press-fit component 14 abutting the underside of the rotation lock with the upper edge.

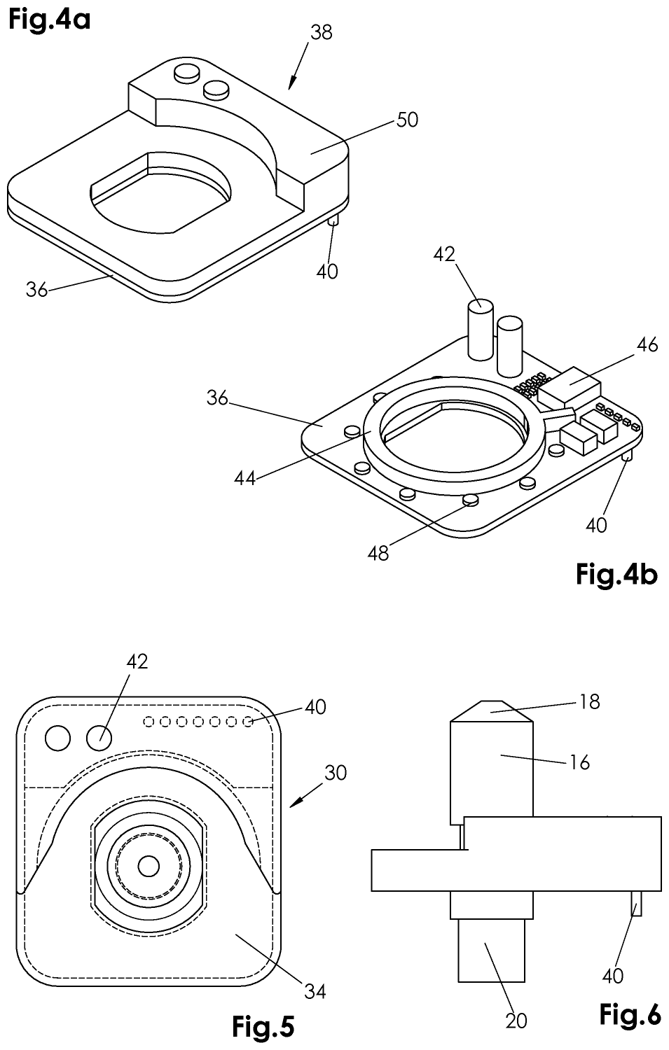

The contact adapter 12 is inserted into the bore hole 28 of the press-fit component 14 of a module of the functional electronics generally designated with numeral 30. The rotation lock 22 is received in a corresponding cutout 32. The position of the press-fit component 14 in the module 30 is illustrated in FIGS. 1 and 3. The module 30 is provided with a plastic mold housing 34. This can be recognized in FIG. 3. It is understood, that different insulating materials may also be used. A printed circuit board in the form of a carrier PCB 36 is arranged in the lower range of the housing 34. A functional electronics is provided on the printed circuit board 36. The installation space 38 provided for the functional electronics within the housing 34 is illustrated in FIG. 4a. An example of a functional electronics with components 44, 46 and 48 is schematically represented in FIG. 4b. It is understood that this is only for illustration purposes. The functional electronics in the present embodiment serves to measure the current flowing through the contact adapter 12. However, different functional electronics may be provided for measuring different physical values, such as voltage or temperature, the material characteristics or for electronical realization of further functionalities in the form of a functional electronics.

On the underside of the printed circuit board 36 contacts 40 of the functional electronics are provided. The contacts 40 are de-coupled from the high current conducting parts of the contact adapter 12 and the printed circuit board where the high current component is used. In particular, signals can be obtained at the contacts and forwarded to a display or a data processing unit for further processing. Signals for controlling and configuring the functional electronics may also be fed to the contacts. In particular, contacts for communication, voltage supply and possibly necessary reference potentials may be provided.

The functional electronics is essentially an electric circuit on a printed circuit board having a well defined task. It is integrated in the housing 34. Two light-emitting diodes (LED) 42 serve as indicators and extend outwards beyond the installation space 50 provided for the components. Thereby, it can be indicated when a contact is established, a measured value exceeds a threshold, is outside a selected admissible range or within such range. Different indicators, such as a digital display or acoustic indicators may also be used.

The housing 34 is provided with a stop 44 for limiting the angular movement of the installable high voltage cable. The stop 44 thereby forms a horizontal rotation limitation. A mechanic guidance 46 serves for additionally securing the installable high current cable.

FIGS. 1, 5 and 6 show the modules of FIG. 2 and FIG. 3 in an assembled state. It can be recognized that the module 30 is suitable also for upgrading existing and known press-fit components 14 and contact adapters 12. It may, therefore, be separately manufactured and sold as a separate component. Its use is independent of the design and the use of the printed circuit board and the corresponding high current components and can—but must not—be designed in such a way that the currents flowing therethrough and the functionalities are practically not affected. In particular, the module 30 with the functional electronics can be independently examined and certified.

The functional electronics can be exchanged upon failure without much effort. For this purpose the module 30 with the functional electronics and the contact adapter 12 are removed from the press-fit component 14. The press-fit component 14 remains in the printed circuit board. Thereafter, the module 30 with the functional electronics is exchanged. The contact adapter 12 can be re-inserted and the high current conductor connected after the module 30 with the functional electronics. No changes are made at the press-fit component or at the high current printed circuit board.

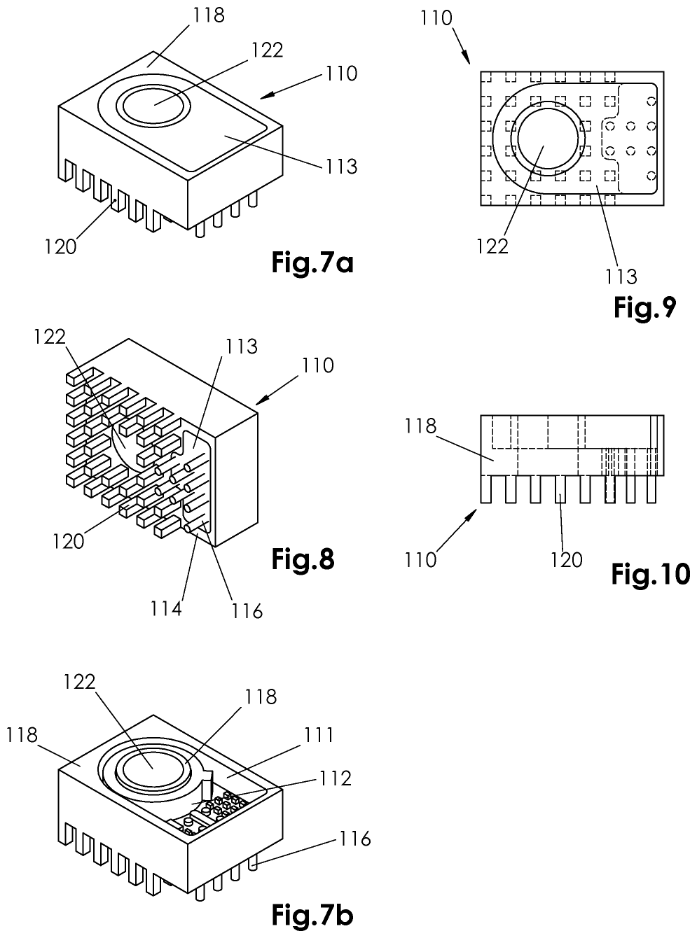

Embodiment 2 (FIG. 7-10)

FIG. 7 to FIG. 10 show a second embodiment of a high current component generally designated with numeral 110 with a metal body 118. Known high current press-fit pins form an integral part of the metal body 118. It is understood, that any other fixing- and contacting form is also suitable. A through bore 122 serves to contact a high current connector, such as an electric cable.

The high current component 110 differs from the known high current components in so far as it is provided with a cutout 111 which accommodates a functional electronics 112. This can be recognized in FIG. 7b. The cutout 111 partly extends to the bottom of the high current component 110 and extends around the through bore 122. The installations space provided for the functional electronics 112 is designated with numeral 113 in FIG. 7a.

FIG. 8 shows the underside 114 of the functional electronics 112 with the corresponding contacts 116 and 120. Contacts 120 serve to establish contact with the printed circuit board. As in the first embodiment contacts 116 serve to, for example, provide communication and/or voltage supply and/or possibly necessary reference potentials.

It can be recognized that the diameters of the high voltage component are changed only very little compared to known high current components without functional electronics. The functional electronics 112 is mounted together with the high voltage component.

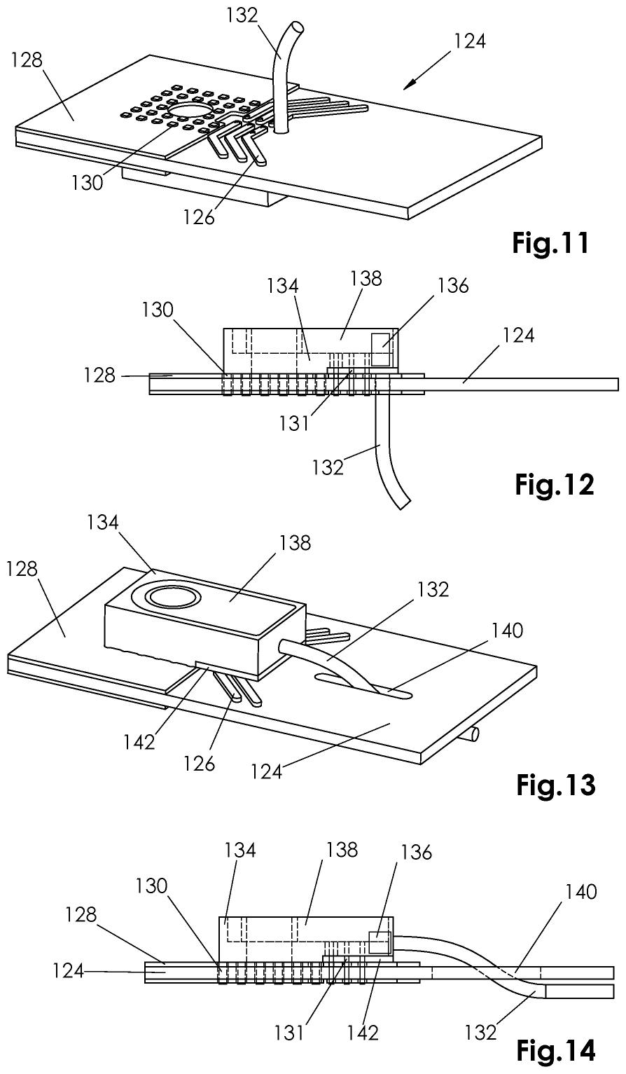

### Embodiment 3 (FIG. 11)

A portion of a printed circuit board 124 is shown in FIG. 11. The printed circuit board 124 is provided with tracks 126 and conductive areas 128 in the usual way. The conductive area 128 shown by way of example, is designed, by way of example, as a high current conductive area of NiAu- (ENIG, ENEPIG) coated copper. It is understood that different suitable materials may also be used. In the present embodiment the tracks on the printed circuit board 124 serve as signal- and reference potential lines.

Electric high current contacts 130 are provided on the conductive area 128. A high current component is press-fitted with its contact pins into such electric contacts 130 from below. In addition to the high current contacts the high current component has electrical contacts 131 which, in particular, may be designed as Skedd-contacts. This is exemplary illustrated in FIG. 12. The contacts 131 are provided for signals and reference potentials. In the present embodiment the high current component is provided with a functional electronics. The communication of the functional electronics is, for example, effected by means of a further processing device. The communication of the functional electronics with, for example, a further processing device is effected by means of an optical signal. A signal generator is provided for this purpose which generates a digital signal fed to an optical fiber 132. Additionally, one or more further optical fibers can be provided which enable a bidirectional communication, for, for example, control- and/or configuration purposes. In this case numeral 132 designates a bundle of optical fibers. The transmission by means of an optical fiber 132 does not require difficult galvanic separation of signal lines and is, therefore, easy to accomplish. In the present case the signal generator is arranged outside of the functional electronics on the underside of the printed circuit board and the optical fiber 132 extends perpendicular to the printed circuit board to the upside. It is understood, that the signal generator may also be provided within the functional electronics inside the press-fit component as described below.

### Embodiment 4 (FIG. 12)

The embodiment shown in FIG. 12 is similar to the 3rd embodiment illustrated in FIG. 11. Accordingly, the same numerals will designate the same components. The signal generator 136, however, is here integrated in the functional electronics 138 in the high current component 134. The optical fiber 132 or the bundle of optical fibers, respectively, is provided on the underside of the high current component 134 and extends perpendicular through the printed circuit board 124. The embodiments show the optical fiber 132 schematically, only. It is understood, that two or more optical fibers may be used for bidirectional communication.

### Embodiment 5 (FIG. 13 and FIG. 14)

FIG. 13 and FIG. 14 show an alternative modification of the extension of the optical fiber. The optical fiber 132 exits the high current component 134 on its side. It may then extend parallel to the printed circuit board 124 towards the outside. The figures illustrate how the optical fiber 132 or the bundle of optical fibers, respectively, extends through a slit 140 to the underside of the printed circuit board 124 and parallel thereafter. It is understood, that the optical fiber 132 or the bundle of optical fibers, respectively, may also extend along the surface of the printed circuit board.

FIGS. 13 and 14 show a high current component which is provided for a continuous high current line. It is understood, that contacting the high current component to the high current line may also be accomplished in any other way. Numeral 142 designates a partial insulation layer on the side facing the printed circuit board 124. Cables are additionally insulated against the high current component by such insulation layer 142. The insulation layer 142 consists of an insulator with a stable form, such as plastic material. It is understood, that viscous insulators may also be used.

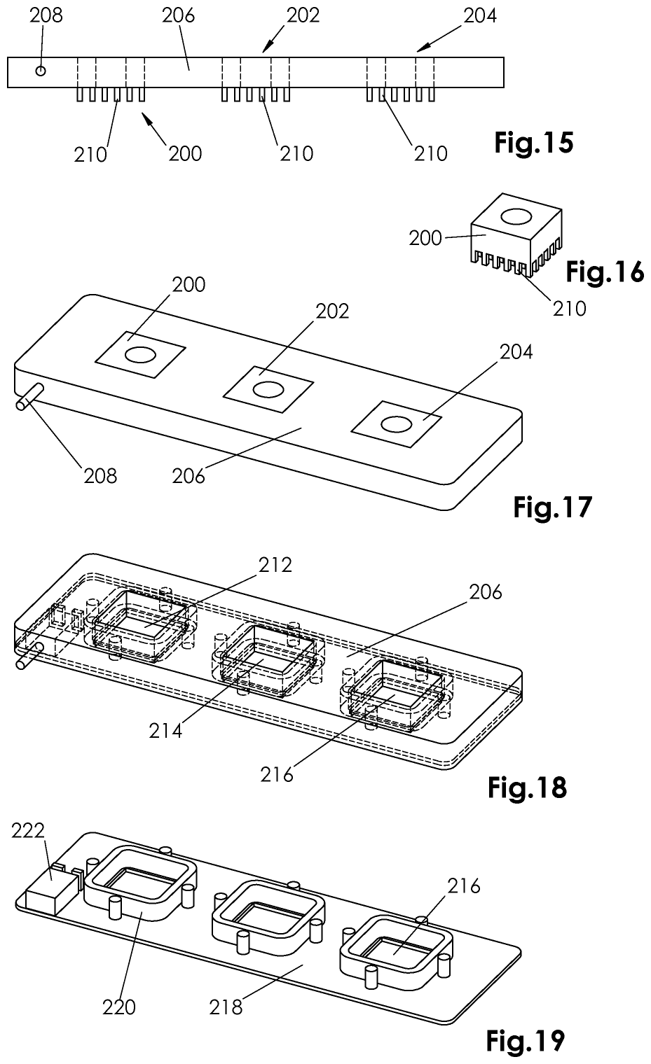

### Embodiment 6 (FIGS. 15 to 19)

FIGS. 15 and 17 schematically show an alternative embodiment with three otherwise known high current components 200, 202 and 204 and a functional electronics 206 according to the present invention. In the present embodiment the functional electronics 206 is molded in a block of synthetic resin. The block of synthetic resin forms a common carrier for the functional electronics and the high current components 200. 202 and 204. The term “functional electronics” shall generally be understood to mean the electronic components with or without carrier, such as a block of synthetic resin. In the present embodiment there are—by way of example—three high current components provided with one common functional electronics 206. The functional electronics 206 comprises parts 220 which cooperate with the high current components. The installation space 212, 214 and 216 for the high current components 200, 202 and 204 can be recognized in FIG. 18 and FIG. 19. The assembly enables, for example, the measurement and processing of the phase of the currents through multipolar contacts. The potential differences caused by phase differences can be used as an energy source for the functional electronics. An optical interface 208 with an optical converter 222 enables the configuration, control and signal transmission towards the outside.

In the present embodiment contacting the high current components 200 is accomplished with contact pins 210 which can be well recognized in FIGS. 15 and 16.

In all embodiments the functional electronics is a low current application which is galvanically separated from the high current application.

The embodiments described above serve to illustrate the invention claimed in the claims. Features which are disclosed together with further features may normally be also used alone or in combination with other features which are explicitly or implicitly disclosed in the text or in the drawings with respect to the embodiments. Sizes and diameters are indicated by way of example only. The person skilled in the art will derive suitable ranges from his/her own specific knowledge and must, therefore, not be discussed here in greater detail. The disclosure of a precise embodiment of a feature does not mean that the invention shall be limited to such a precise embodiment. Moreover, the feature may be realized by many others which are well known to the person skilled in the art. The invention may, therefore, not be only realized in the form of the described embodiments but by all embodiments which are covered by the protective scope of the accompanying claims.

The terms “up”, “down”, “left” and “right” only relate to the accompanying drawings. It is understood, that the claimed devices may also assume a different orientation. The term “comprising” and the term “including” mean that further not-mentioned components may be provided. The term “essentially”, “mainly” or “mostly” means all features which have a property or a content more than others, i.e. more than all other components or features of the kind, i.e. with two components more than 50%.

1. A functional electronics for configured to be used with a high current component said high current component configured to electrically and mechanically connect to a high current printed circuit board or any other mechanic carrier substrate used for a high current circuitry
wherein
said functional electronics is provided with electronic parts, said electronic parts configured for measuring the properties of either an electric current flowing through said high current component, or an electric voltage applied to said high current component, or for carrying out another electronic functionality; and
wherein said functional electronics is held at said high current component, or
at any other common carrier carrying said functional electronics and said high current component.

2. The functional electronics of claim 1, and wherein said functional electronics is adapted to be integrated into the high current component.

3. The functional electronics of claim 1, and further comprising a housing or a carrier material adapted to be modular stuck onto the high current component or fixed to a high current component.

4. The functional electronics of claim 1, and wherein said functional electronics is adapted to be inserted into a cutout or into a cavity within the high current component.

5. The functional electronics of claim 1, and wherein contacts are provided which are galvanically de-coupled from contacts of a high current component and where signals of said functional electronics can be obtained.

6. The functional electronics of claim 1, and further comprising an optical and/or acoustic signal generator, which indicates the presence or absence of a state of a component.

7. The functional electronics of claim 6, and wherein said optical signal generator comprises an LED or OLED.

8. The functional electronics of claim 1, and further comprising one or more electronic parts and at least one data interface adapted to configure said one or more electronic parts.

9. The functional electronics of claim 1, and further comprising an IO-link or any other standardized communication interface.

10. The functional electronics of claim 1, and further comprising an optical communication interface.

11. The functional electronics according to claim 10, and wherein said communication interface is bidirectional.

12. The functional electronics according to claim 10, comprising an optical signal generator and wherein an optical fiber configured to receive said optical signals of a said signal generator for transmitting the signals to a processing unit.

13. A high current component for electrically and mechanically connecting to a high current printed circuit board or any other mechanic carrier substrate for a high current circuitry, comprising a functional electronics according to claim 1.

14. The component of claim 13, said component being designed as a press-fit component, as a screw element, that it has snap-in contacts, touch fastener (Velcro) fastenings or is plug-in element.

15. The component of claim 13, and consisting of said functional electronics and otherwise only of a coated or uncoated, homogenous, electrically conductive material.

16. The component of claim 15, and further comprising an electrically conducting metal body and said functional electronics being accommodated in a cutout or in a cavity within such metal body.

17. (canceled)

18. The component of claim 13, said component being designed for currents above 16 A, preferably above 50 A and most preferably above 100 A.

19. The component of claim 13, and wherein a thread, a plug-in contact or another surface contact is provided for connecting high current lines.

20. The component of claim 13, and wherein
(a) said functional electronics is arranged in or upon a carrier material or in a housing which cannot be removed from said carrier substrate without destruction, wherein
(b) said carrier material is galvanically separate from said carrier substrate; and
(c) said carrier material or housing is provided with further cutouts for further threads, plug-ins or other surface contacts for connecting high current lines which together use at least portions of the functionality of the functional electronics.

21. The component of claim 13, and further comprising a first and a second group of contacts; said first group of contacts provided for contacting contacts at a printed circuit board, said first group of contacts being galvanically de-coupled from said second group of contacts and wherein signals of said functional electronics can be obtained at said first group of contacts.
